(19) United States
(12) Patent Application Publication
(10) Pub. No.: US 2011/0232751 A1
(43) Pub. Date: Sep. 29, 2011

(54) METHOD FOR MACHINING THE SURFACE OF A WAFER FOR PRODUCING A SOLAR CELL, AND WAFER

(75) Inventor: Dirk Habermann, Kirchzarten (DE)

(73) Assignee: Gebr. Schmid GmbH & Co., Freudenstadt (DE)

(21) Appl. No.: 13/154,539

(22) Filed: Jun. 7, 2011

Related U.S. Application Data
(63) Continuation of application No. PCT/EP2009/066556, filed on Dec. 7, 2009.

(30) Foreign Application Priority Data
Dec. 8, 2008 (DE) 10 2008 063 558.8

(51) Int. Cl. H01L 31/0224; H01L 31/18

(52) U.S. Cl. 136/256; 438/72; 257/E31.127

(57) ABSTRACT

In a method for the treatment of the surface of a wafer for producing a solar cell, onto which wafer an antireflection and passivation layer has been applied onto a p-doped layer in a step preceding the method, the surface is treated in a processing step and then a subsequent metallization on the surface of the wafer for producing contacts for the solar cell takes place. This processing step is for passivation or for removal of the p-doped layer in the region of disturbances such as scratches, defect sites, pinholes and inhomogeneous regions in the antireflection and passivation layer. It is thus possible to avoid metal depositions at these disturbances.

### FIELD OF APPLICATION AND PRIOR ART

The invention relates to a method for the treatment of the surface of a wafer for producing a solar cell, and to a wafer for producing a solar cell, which has been treated by means of such a method.

When metalizing solar cells for producing a metallic ohmic contact, electrolytic and chemical electroless metallization is also used besides screen printing methods. These metallic contacts are often composed of metallization layers comprising Ag, Cu, Ni and tin and combinations thereof.

One significant problem in the metallization of these layers is the so-called parasitic coating of individual regions with defects at the antireflection and passivation layer. In this case, metal is deposited in the region of for example scratches, pinholes and inhomogeneous regions in the antireflection and passivation layer and also simple surface defects such as, for example, fingerprints from manual handling.

These parasitic metal depositions reduce the optically active surface of solar cells and thus decrease the performance of the solar cell. An additional factor is that these parasitic depositions also significantly reduce qualitatively the appearance of the solar cells.

### OBJECT AND HOW IT IS ACHIEVED

The invention is based on the object of providing a method mentioned in the introduction for the surface treatment of a wafer, and also a corresponding wafer, with which it is possible to avoid the problem of parasitic metal deposition at the surface of a wafer for solar cells during the contact metallization.

This object is achieved by means of a method having the features of Claim 1 and also by means of a wafer having the features of Claim 17. Advantageous and preferred configurations of the invention are the subject matter of the further claims and are explained in greater detail below. The wording of the claims is incorporated by express reference in the content of the description.

In the method for the surface treatment of a wafer during the production process to form a solar cell, at a specific point in the method sequence, an antireflection and passivation layer is applied to the p-doped layer of the silicon wafer. This is known for example from US 2010/018580 A1, to which is pointed explicitly. Said antireflection and passivation layer improves the radiation of light into the finished solar cell so as to increase the efficiency and the energy yield. This is then usually followed by the above-mentioned metallization or application of contacts composed of metal onto said antireflection and passivation layer for the purpose of making electrical contact with the solar cell. According to the invention, prior to such a metallization or metal deposition on the surface of the wafer, the surface is treated in a processing step for passivation or for removal of the p-doped layer in the region of disturbances such as scratches, defect sites, pinholes or inhomogeneous regions or the like. This is because these problem sites—referred to generally as disturbances—in the antireflection and passivation layer could otherwise bring about metal depositions thereon. This brings about an undesired shading of the solar cell and hence a reduction of the energy yield, on the one hand, and could produce undesired conductive connections, on the other hand. By means of passivation or removal of the p-doped layer in this region of disturbances, it is possible to avoid not just a possibly undesired electrically conductive contact, but any metal deposition at said disturbance whatsoever. Such a passivation prevents the deposition of metal at said disturbance on account of the neutral electrical properties then present. Specifically, there are no suitable surface charges present for metal attachment. Removal of the p-doped layer in the region of a disturbance has a similar effect since there is then likewise no suitable or necessary surface charge present for the disturbing deposition of metal.

Subsequent metallization can advantageously be effected electrolytically, as is known per se and is customary. It may possibly even be effected with a degree of light assistance. An electrolytic metal deposition can advantageously be effected as so-called Ag-LIP. As an alternative, a known electroless metallization can also be effected, in particular as known chemical metallization.

A treatment according to the invention of the surface of the wafer in the region of disturbances, in particular for the local removal of the p-doped layer, can be effected using etching solution in an etching step. The duration of such an etching step can vary and lie between a plurality of seconds and a plurality of minutes. One possible and advantageous etching solution is H₂SO₄, alternatively also H₂O₂. Successful experiments have been carried out using these etching solutions in the context of the invention. As a further aspect when choosing the etching solution, consideration should be given to choosing the etching solution such that it attacks the antireflection and passivation layer of the solar cell only negligibly, that is to say does not produce further above-mentioned disturbances which then act in a similar manner to scratches or defect sites upon subsequent application of the metallic contacts. The etching solution is advantageously chosen such that it leaves the antireflection and passivation layer undamaged, that is to say virtually does not attack it at all. This can advantageously also be set by means of process parameters during the etching step, for example duration and/or temperature.

An etching solution can also be chosen with regard to the aspect that it only selectively etches the p-doped layer in order to locally remove it in the region of the disturbance. Also conceivable here is an advantageously automated method for applying the etching solution as far as possible only in the region of such disturbances which have been identified and localized beforehand by means of analysis methods, in particular in automated fashion. Thus, not only can the consumption of etching solution be greatly reduced, but an unnecessary and damaging impairment of the antireflection and passivation layer is avoided in the remaining regions containing no disturbances.

As an alternative to the treatment in an etching step using etching solution, the surface of the wafer can be subjected to a strongly oxidizing gaseous medium generally or, in turn locally, in the region of the disturbances alone. A strongly oxidizing medium can oxidize and in the process passivate the surface of the wafer precisely in the region of the disturbances, that is to say as far as possible not in the other region of the desired antireflection and passivation layer. The abovementioned surface charges can thus likewise be eliminated. For this purpose, as an alternative to a treatment with a gaseous medium having a strongly oxidizing effect, said medium can also be dissolved in an aqueous solution and the wafer surface can then be treated with the aqueous solution and with the oxidizing gas therein. The advantage of such an oxidizing medium dissolved in an aqueous solution can reside in the fact that application locally exclusively or in a manner as delimited as possible to disturbance regions can be implemented better than using a gas, which generally spreads over the wafer surface after application. As an alternative, when a strongly oxidizing gas is used, a locally greatly delimited effect can likewise be achieved by means of suitable extraction.

In a manner similar to that described above for the etching step, the duration of the oxidization of the wafer surface can also vary greatly and range from a few seconds to a plurality of minutes. This is dependent primarily on the oxidation effect of the gas, but simultaneously also on a possibly precisely identified and determined intensity of the disturbance, which possibly requires oxidation to a varying extent or intensity.

Provision may advantageously be made, in order to identify said disturbances, for using optical systems, for example cameras, and thereby searching the surface in regions or in its entirety by scanning. Systems of this type which are known per se can be used here, which then pass the data to a controller, which in turn controls the step of targeted elimination of the disturbance at this location.

After the step according to the invention for removal or passivation of the p-doped layer in the region of disturbances, therefore, a metal deposition for producing the contacts is advantageously effected. Particularly advantageously, a cleaning step is effected in between, such that after the removal or passivation of the wafer surface, the latter is first of all cleaned thoroughly before the metallization is then effected.

These and further features emerge not only from the claims but also from the description and the drawings, where the individual features can be realized in each case by themselves or as a plurality in the form of subcombinations in an embodiment of the invention and in other fields and can constitute advantageous and inherently protectable embodiments for which protection is claimed here. The subdivision of the application into individual sections and sub-headings do not restrict the general validity of the statements made thereunder.

### BRIEF DESCRIPTION OF THE DRAWINGS

An exemplary embodiment of the invention is illustrated schematically in the drawings and is explained in greater detail below. In the drawings:

FIG. 1 shows a wafer for producing a solar cell with a scratch in the antireflection and passivation layer right down to the p-doped layer,

FIG. 2 shows an etching operation in the region of the scratch in accordance with FIG. 1, and

FIG. 3 shows the wafer after the etching operation in accordance with FIG. 2 with the p-doped layer removed by the etching in the region of the scratch.

### DETAILED DESCRIPTION OF THE EXEMPLARY EMBODIMENT

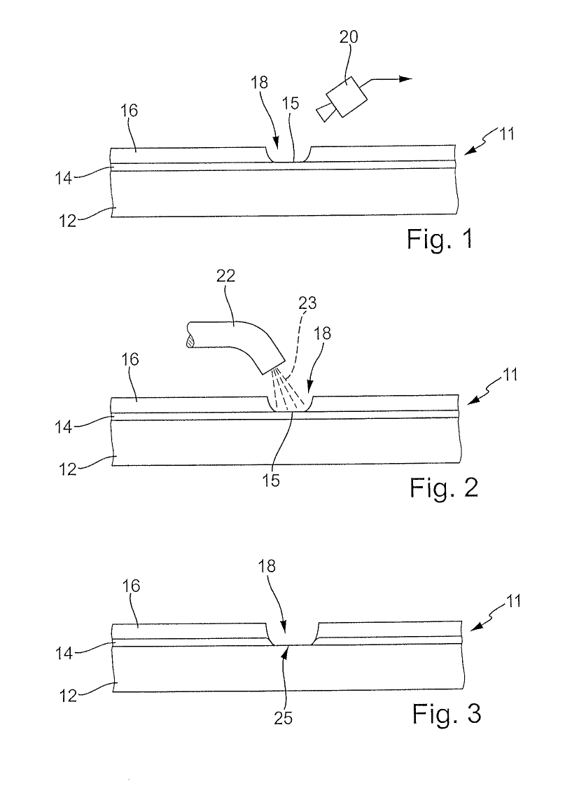

FIG. 1 illustrates a wafer 11 during the process for producing a solar cell. The wafer 11 has a silicon substrate 12 with a p-doped layer 14 at its top side. The p-doped layer 14, in turn, is covered by a conventional antireflection and passivation layer 16. In this respect, the wafer 11 corresponds to a conventional wafer after the application of the antireflection and passivation layer, in particular before the step of a subsequent metallization or metal deposition. Metallic contacts are thereby produced on the antireflection and passivation layer 16.

A scratch 18 is discernibly illustrated in the antireflection and passivation layer 16, which scratch may have arisen for example as a result of handling errors or the like. There could also be some other disturbance mentioned above. The scratch 18 goes right down to the p-doped layer 14, such that the latter has an uncovered region 15 in the region of the scratch 18. In the course of a metallization step that then conventionally follows, metal would deposit here, as has been described in the introduction, which is undesirable, however.

FIG. 1 illustrates an optical scanning system 20, which is advantageously movable or else can simultaneously detect and evaluate the entire top side of the wafer 11. The optical scanning system 20 identifies the scratch 18 and the size thereof, the course thereof and also whether it goes right down to the p-doped layer 14, that is to say has to be rendered harmless.

On the basis of the information sent to a control system (not illustrated) by the optical scanning system 20, a controllable nozzle 22 can then be brought in according to FIG. 2. Said nozzle 22 applies etching liquid 23 in the region of the scratch 18. In particular, the etching liquid 23 is applied directly to the uncovered region 15 of the p-doped layer 14. The etching liquid can be an acid mentioned above. The duration of the etching operation or of the action of the etching solution 23 is dependent both on the latter's own composition and the type and construction of the antireflection and passivation layer 16.

FIG. 3 illustrates how the wafer 11 appears after the etching step in accordance with FIG. 2 and a cleaning step that possibly succeeds said etching step, said cleaning step not being illustrated here since it can be carried out very easily. It can be discerned how the antireflection and passivation layer 16 is not attacked in the region of the scratch 18, but in return the p-doped layer 14 or the uncovered region 15 is removed. It is merely possible here that a region 25 of the silicon substrate 12 itself has possibly, as indicated in the drawing, likewise been incipiently etched or removed somewhat. However, this is not considered to be disturbing for the functioning and performance of the finished solar cell. During a subsequent metallization step, no metal can deposit onto the now uncovered region 25 of the silicon substrate 12. Consequently, this problem can be eliminated.

It can easily be discerned how the method according to the invention can be modified with reference to FIGS. 1 to 3. Instead of an etching solution 23 together with a fine nozzle 22, large-area spraying with etching solution can be effected. Furthermore, instead of a liquid etching solution, an oxidizing gas can be applied, which, under certain circumstances, can equally be directed in a targeted manner onto scratches or the other defects mentioned above. During oxidation, generally the p-doped layer or the uncovered region 15 is then not removed, but rather passivated, with the result that likewise no metal can deposit during a subsequent metallization.

1. Method for treatment of a surface of a wafer for producing a solar cell, wherein said wafer has a p-doped layer and an antireflection and passivation layer has been applied onto said p-doped layer in a step preceding said method, wherein said antireflection and passivation layer has disturbances such as scratches, defect sites, pinholes and inhomogeneous regions and wherein said wafer surface is treated in a processing step for passivation or for removal of said p-doped layer, respectively, in said region of said disturbances in said antireflection and passivation layer in order to avoid a deposition of metal at said disturbances during a subsequent metal deposition, wherein following that, a subsequent metallization or said metal deposition takes place on said surface of said wafer for producing contacts for said solar cell.

2. Method according to claim 1, wherein said treatment of said surface of said wafer in said region of disturbances is performed in an etching step using etching solution.

3. Method according to claim 2, wherein said etching step lasts for a plurality of seconds to a plurality of minutes.

4. Method according to claim 2, wherein said etching solution is H₂SO₄.

5. Method according to claim 2, wherein said etching solution is H₂O₂.

6. Method according to claim 2, wherein said etching solution is chosen such that it attacks said antireflection and passivation layer of said solar cell only negligibly.

7. Method according to claim 2, wherein said etching solution is chosen such that it leaves said antireflection and passivation layer of the solar cell undamaged.

8. Method according to claim 2, wherein said etching solution is chosen such that said p-doped layer is etched selectively in order to remove said p-doped layer locally in said region of disturbances.

9. Method according to claim 1, wherein for said treatment of said surface of said wafer in said region of disturbances, said wafer is subjected to a strongly oxidizing gaseous medium as an oxidation.

10. Method according to claim 9, wherein said wafer is subjected to an oxidizing gas dissolved in an aqueous solution.

11. Method according to claim 9, wherein said duration of said oxidation of the surface of the wafer to be treated lasts for a few seconds up to a plurality of minutes.

12. Method according to claim 9, wherein said strongly oxidizing medium oxidizes and passivates said surface of said wafer in said region of disturbances.

13. Method according to claim 1, wherein after said step for removal or passivation of said p-doped layer in said region of disturbances, a metal deposition is effected.

14. Method according to claim 13, wherein said metal deposition is effected with an intervening cleaning step as an inter-mediate step.

15. Method according to claim 1, wherein said metal deposition is effected galvanically.

16. Method according to claim 15, wherein said metal deposition is effected galvanically as an Ag-LIP.

17. Wafer for producing a solar cell, wherein an antireflection and passivation layer applied to its surface on a p-doped layer has been treated by means of said method according to claim 1.
